(19) United States
(12) Patent Application Publication
(10) Pub. No.: US 2005/0012188 A1
(43) Pub. Date: Jan. 20, 2005

(54) Device for the hermetic encapsulation of a component that must be protected against all stresses

(76) Inventor: Christian Val, Les Chevreuse (FR)

Correspondence Address: LOWE HAUPTMAN GILMAN & BERNER, LLP, 1700 DIAGNOSTIC ROAD, SUITE 300, ALEXANDRIA, VA, 22314, US

(21) Appl. No.: 10/494,421

(22) PCT Filed: Oct. 15, 2002
(86) PCT No.: PCT/FR02/03524

(30) Foreign Application Priority Data
Nov. 9, 2001 (FR) 01/14543

(51) Int. Cl. H01L 23/02

(52) U.S. Cl. 257/678

(57) ABSTRACT

The invention relates to a device for the hermetic encapsulation of a component that has to be protected from any stress. The component (5) is fastened to a substrate (15) that carries, on its other face, a temperature-regulating element (17) fastened by adhesive bonding (16). This assembly is placed in a package comprising two portions (11, 12) joined together by adhesive bonding (13) with a passage for optical links (6) and for electrical connections (18, 142). It is supported by protuberances (19) of one portion (11) of the package. Bonded to the other portion (12) is a three-dimensional interconnection block (14) forming the temperature-regulating electronics. The block, the package (11, 12) and a minimum length (L) of the links and connections are encapsulated in a mineral protective layer (4′). The invention applies especially to optoelectronic components and to MEMS components.

The invention relates to a device for the hermetic encapsulation of a component that has to be protected from any stress, of the type comprising a package formed from two portions joined together to define an internal volume in which the component is placed in a dry atmosphere.

A number of applications are faced with the problem of very fragile components that can withstand no mechanical or thermal stress and have to be absolutely protected from moisture and/or oxidation.

These problems arise in particular in the case of optical or optoelectronic components in which moisture will disturb or degrade the performance of the component and its optical input and output coupling, especially with optical fibers. In addition, any stress may modify this coupling and cause unacceptable losses. Finally, such components have to be very precisely temperature-regulated, hence electrical conductor outputs and considerable associated electronics.

These problems are also encountered in MEMS (Micro-ElectroMechanical Systems). Such components result from the integration of mechanical elements, sensors, actuators and electronics on a common silicon substrate thanks to the use of microfabrication technologies. They are extremely sensitive to moisture, which will stick any moving element, and to stresses, even of low amplitude, which will destroy the calibrations made in the laboratory or in the factory (for example in the case of sensors, especially those for space applications).

These problems could be remedied by a protection system obtained by plastic molding or encapsulation. However, this solution is completely excluded not only in the case of MEMS (the moving parts to be left free) but also in the case of all components that cannot withstand the stresses and/or heating involved in this technology.

One conceivable solution is therefore packaging. To do this, the component is placed inside a volume defined by hollow parts, at least in the case of one of them, which are joined together, the internal volume containing a dry atmosphere (nitrogen, dry air, etc.). The major problem is hermeticity, on the one hand as regards the construction of the portions of the package themselves and, on the other hand, as regards their assembly and the passage for the optical and/or electrical connections with the outside. As regards the package, it is possible to use metal parts, but this is more expensive than a plastic package. As regards the assembly and passage for the connections, simply using adhesives cannot be envisioned as these cannot form a hermetic seal.

Here again, it is therefore necessary to use expensive brazing solutions. In particular, to seal the passage for optical fibers, the glass fibers must be brazed, which is difficult and very expensive.

The object of the invention is to remedy these drawbacks using simple and inexpensive materials and structures, while still ensuring hermeticity of excellent quality.

According to a first aspect, the invention therefore provides a device for the hermetic encapsulation of a component that has to be protected from any stress, of the type comprising a package formed from at least two portions joined together to define an internal volume in which the component is placed in a dry atmosphere, said device being characterized in that the two portions of the package are joined together by adhesive bonding or via a substrate that supports said component, and in that the entire package is protected by a mineral protective layer that also extends over a predetermined minimum length along the connections and/or links leaving the package.

Thus, whatever the nature of the material of the package (plastic, ceramic or metal), the hermeticity is provided by the mineral layer. Moreover, at the passage for the links or connections where moisture could penetrate, in particular along plastic sheaths of these connections/links, the hermeticity is provided by increasing, by a minimum length, the path to be traveled in order to reach the inside of the package. This minimum length is preferably of the order of a few millimeters.

According to another advantageous aspect of the invention, the device is characterized in that said protective layer is a layer of SiOₓ where x is substantially between 1.4 and 2.

It may be advantageous to start with a value of x of less than 2 in contact with the package so as to ensure optimum adhesion and to reach the value of 2 on the outside, for maximum hermeticity, the SiO₂ material being very hard and hermetic.

One embodiment of the invention suitable for MEMS provides a device of the abovementioned type characterized in that said component is a MEMS, mounted on a substrate carrying connection conductors, in that said package is formed from two portions placed facing each other on either side of the substrate and adhesively bonded to the latter, said protective layer extending over said two portions and along said conductors and the substrate over said minimum length.

Another embodiment of the invention suitable for optical or optoelectronic components provides a device characterized in that said component is an optical or optoelectronic component fastened to a first face of a plane substrate, in that the other face of said substrate bears, facing the component, a temperature-regulating element, supplied by an electronic temperature-regulating circuit, and in that a first portion of said package includes at least one internal protuberance acting as support for said substrate.

Furthermore, if the electronic temperature-regulating circuit is produced in the form of a three-dimensional interconnection block, this may be fastened by adhesive bonding to one of the portions of the package and encapsulated in the layer for protecting the assembly, or else may itself constitute one of the portions of the package in order to be joined to the other portion by adhesive bonding.

The invention will be more clearly understood and other features and advantages will become apparent from the description below and from the appended drawings in which:

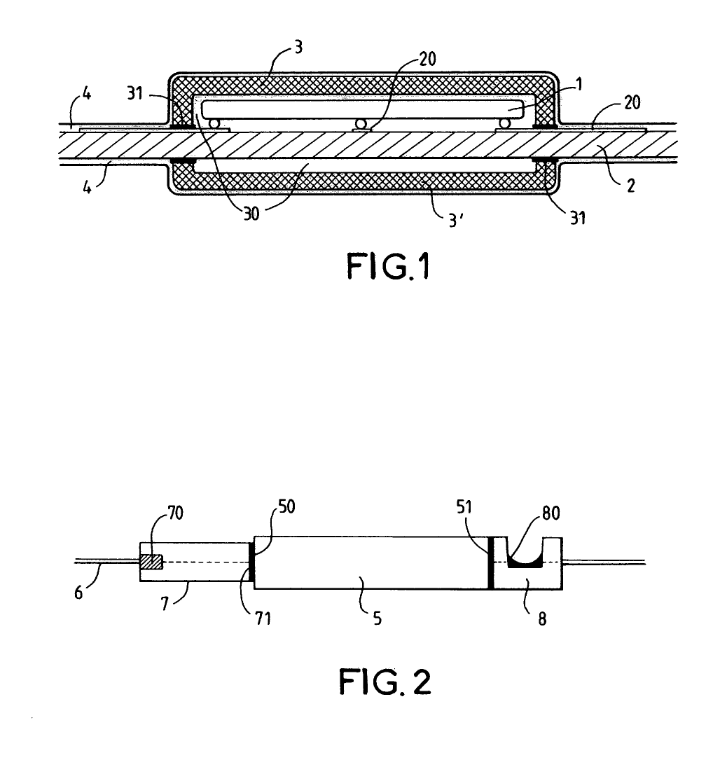

FIG. 1 shows one embodiment of the encapsulation device according to the invention, suitable for a MEMS;

FIG. 2 is a diagram showing the principle of an optoelectronic component;

FIG. 3 is a sectional representation of another embodiment of the device according to the invention;

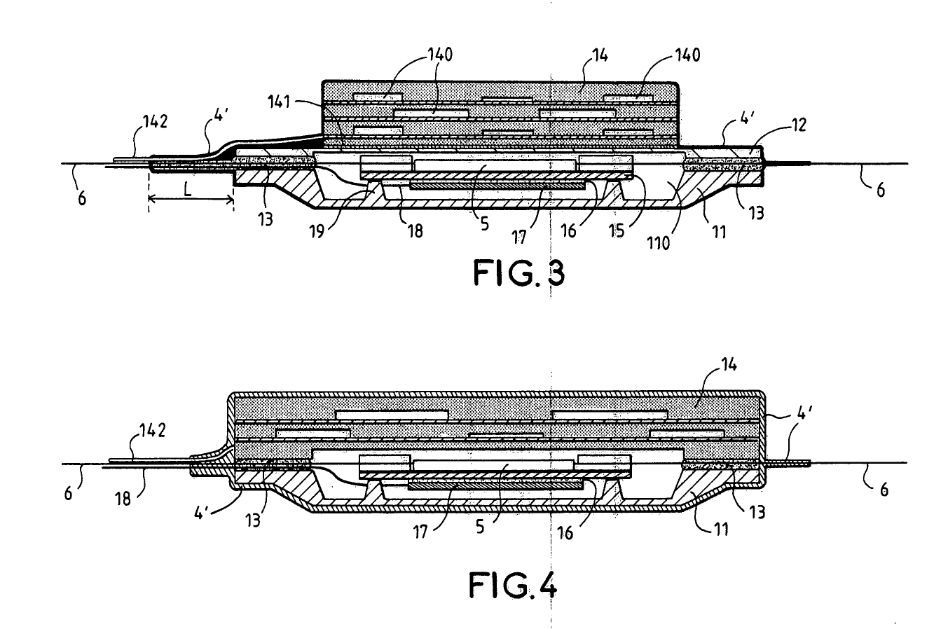

FIG. 4 shows an alternative embodiment of the device of FIG. 3 in which one portion of the package is formed by a three-dimensional interconnection block;

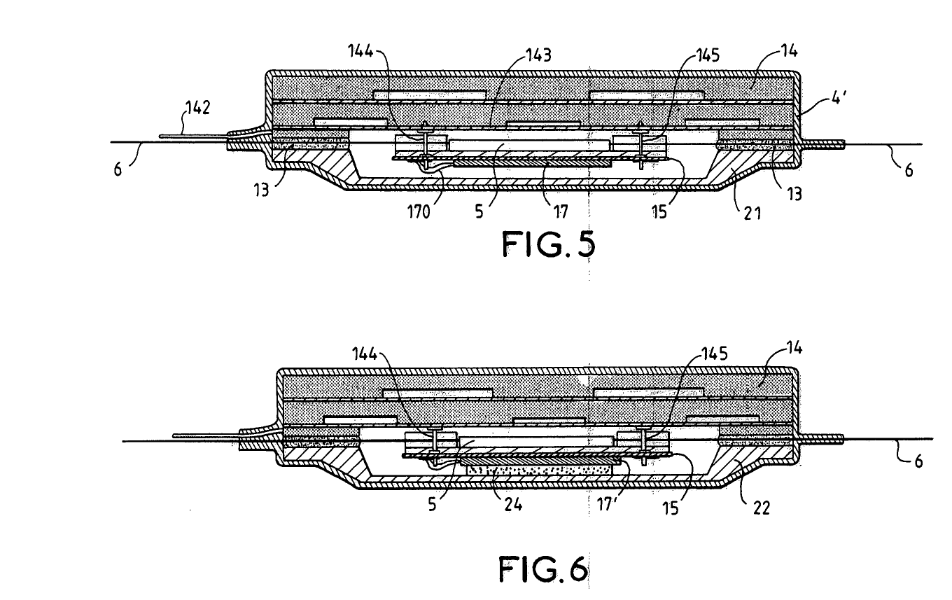

FIG. 5 is another embodiment in which the support for the component is provided by said block; and

FIG. 6 is an alternative embodiment of the device of FIG. 5.

As already explained above, the basic principle of the invention is to use a package in the form of at least two portions joined together by adhesive bonding and to ensure hermeticity by a mineral protective layer extending over the package and over a minimum length of the connections.

FIG. 1 shows a first embodiment of the invention, suitable for a MEMS. This component 1 is mounted on a substrate 2 bearing connection conductors 20. The component 1 and the facing portion of the substrate are enclosed in a volume defined by a package made up of two portions 3, 3′ constituting cavities 30 that are placed facing each other on either side of the substrate and adhesively bonded to the latter by a suitable adhesive 31. The portions 3, 3′ of the package may be made of any conventional material for this use (plastic, ceramic, metal, etc.). The internal volume of the cavities is filled with a dry atmosphere (nitrogen, dry air, etc.). The hermeticity of the assembly is provided, according to the invention, by a mineral protective layer 4 extending over the two portions 3, 3′ and over the substrate 2 and the conductors 20, over a predetermined minimum length in order to avoid any penetration of moisture or any other contaminant, as will be described again later.

The layer 4 may be composed, for example, of an oxide or a nitride, particularly silicon oxide or silicon nitride, although this is not a limitation. It suffices for the chosen material to exhibit good adhesion to the portions to be covered and the required hermeticity and resistance properties.

Advantageously, a layer of silicon oxide SiOₓ, where the index x varies between 1.4 and 2, may be used. This material passes from a soft plastic state when x is around 1.4 to a very hard state when x=2.

Such a layer may be deposited by PECVD (plasma-enhanced chemical vapor deposition). Advantageously, the value of x goes from below 2, in contact with the package, in order to ensure optimum adhesion, up to a value of 2 on the outside, in order to provide hermeticity and a maximum strength. However, it is also possible to choose a single intermediate value that ensures good hermeticity, good adhesion and a certain amount of flexibility.

Preferably, the thickness of the protective layer is between 0.1 and 5 microns. A preferred value is around 0.5 microns.

FIG. 2 is a diagram showing the principle of an optoelectronic component inserted into a fiber-optic link. The component 5 has an entry face 50 and an exit face 51 that are coupled to fibers 6, which may or may not be sheathed with a polymer and are held in place and terminated by ferrules 7 or a V-shaped glass block 8. The links and holding means are provided by various bonds 70, 71, 80, which are not hermetic and therefore allow the optical quality and the coupling to be degraded by letting moisture through. The body of the component 5 must also be protected against moisture (or possibly oxidation).

FIG. 3 shows, in section, a first embodiment of the encapsulation device according to the invention for a component of this type. In FIG. 3, the component 5 is mounted on a substrate 15, for example by adhesive bonding to one face of the plane substrate. The other face of the substrate carries, fastened by bonding 16, a heating or cooling thermal element 17 for regulating the temperature. This regulation must in general be very precise and therefore requires an electronic temperature-regulating circuit of not inconsiderable size. The component 5/substrate 15/thermal element 17 assembly is placed in the internal volume of a package composed, for example, of two portions 11, 12 joined together by adhesive bonding 13. The assembly 5, 15, 17 is supported, for example, by at least one internal protuberance 19 in the portion 11 of the package. The substrate 15 may be bonded to these protuberances in order to ensure mechanical retention while maintaining good thermal insulation with respect to the outside thanks to the dry atmosphere existing inside the volume 110.

As was explained above, the component 5 and the thermal element 17 are usually combined with an electronic circuit, in particular for regulating the temperature. To limit the size of this electronic circuit, it is made in the form of a three-dimensional interconnection block 14. The construction of such a block is known per se and a description of it may be found, for example, in French patent No. 2 688 630. Thus, a circuit produced in the form of a very compact block incorporating electronic components 140 is obtained. This block 14 is fastened to a portion 12 of the package, for example by adhesive bonding 141.

It is clear that the package 11, 12 has to allow passage for the fibers 6 and the electrical conductors 18 supplying the thermal regulation element 17. Moreover, the block 14 is generally connected to the outside by a flat cable 142. According to the invention, hermeticity is provided by depositing a mineral protective layer 4′, as already described in relation to FIG. 1, which encapsulates the package 11, 12/three-dimensional block 14 assembly. Moreover, this protective layer must extend along the fiber-optic links 6 and the electrical connections 18, 142 to the outside over a predetermined minimum length L. This is because, as mentioned, the bonded joints and the plastic sheaths have a certain longitudinal permeability which, of course, decreases with the length of the path that the contaminating element must exceed. The hermeticity at these passages is maximized by imposing an additional path L.

Preferably, the length L is of the order of a few millimeters.

One solution for reducing the minimum length could consist in partly stripping the electrical connections and links at the outlet of the package over a short length (less than 1 millimeter for example) and in stopping the mineral layer on these stripped parts. The contact between mineral layer and the glass of the fibers or between the mineral layer and the metal of the conductors ensures perfect hermeticity of these outlets.

An alternative embodiment of the device of FIG. 3 is shown in FIG. 4.

In this embodiment, the portion 12 of the package of FIG. 3 is replaced with the block 14 itself, which is fastened by adhesive bonding 13 to the first portion 11 of the package in order to define the internal volume in which the component 5 is placed. The same reference numerals refer to the same elements as in FIG. 3. This embodiment has the advantage of omitting one of the portions of the package.

FIG. 5 shows another embodiment derived from that in FIG. 4. In this embodiment, the block 14 comprises, toward the inside of the package, conducting connection pins 144, 145 approximately perpendicular to the internal face 143 of the block. The substrate 15, carrying the component 5 and the temperature-regulating element 17, is mechanically fastened to these pins. Thus, there is no longer any need for the protuberances 19. In addition, these pins provide the electrical link between the element 17 and the electronic circuit 14. The supply wires 170 for the element 17 are connected to these pins by soldering and/or by means of conducting tracks on the substrate.

One advantage of this embodiment is that the supply wires for the thermal element 17 no longer need to pass through the package to the outside, hence a reduction in the number of regions where hermeticity must be enhanced.

FIG. 6 shows an alternative embodiment of FIG. 5, the same reference numerals referring to the same elements in all the figures. In this embodiment, a Peltier-effect cooling element 17′ is used as thermal temperature-regulating element, said element being fastened, as previously, by adhesive bonding to the substrate 15, the cold face of this element 17′ being turned toward the substrate and the component. To ensure good thermal dissipation to the outside of the thermal energy developed on the hot face of the element 17′, the package portion 22 is made of a good thermal conductor, for example a metal, and a coupling layer 24 is placed between said hot face and the internal face of the package portion 22 in order to ensure thermal coupling between the thermal element 17′ and the package 22.

Of course, the illustrative embodiments described in no way limit the invention, in particular any component having similar requirements as regards protection against the environment and stresses may be encapsulated using the principles of the invention.

1. A device for the hermetic encapsulation of a component that has to be protected from any stress, comprising:
a package formed from two portions joined together to define an internal volume in which the component is placed in a dry atmosphere, wherein the two portions of the package are joined together by adhesive bonding or via a substrate that supports said component, and in which the entire package is protected by a mineral protective layer that also extends over a predetermined minimum length along the connections and/or links leaving the package.

2. The device as claimed in claim 1, wherein said predetermined minimum length is of the order of a few millimeters.

3. The device as claimed in claim 1, wherein said protective layer is a layer of SiOₓ where x is substantially between 1.4 and 2.

4. The device as claimed in claim 3, wherein the value of x varies from a first value of less than 2 in contact with the package, determined to ensure optimum adhesion, up to the value of 2 on the outside, in order to ensure maximum hermeticity.

5. The device as claimed in claim 3, wherein the thickness of said protective layer is substantially between 0.1 and 5 microns.

6. The device as claimed in claim 5, wherein said thickness is around 0.5 microns.

7. The device as claimed in claim 1, wherein said component is a MEMS, mounted on a substrate carrying connection conductors, in which said package is formed from two portions placed facing each other on either side of the substrate and adhesively bonded to the latter, said protective layer extending over said two portions and along said conductors and the substrate over said minimum length.

8. The device as claimed in claim 1, wherein said component is an optical or electrooptic component fastened to a first face of a plane substrate, in which the other face of said substrate bears, facing the component, a temperature-regulating element, supplied by an electronic temperature-regulating circuit, and in which a first portion of said package includes at least one internal protuberance acting as support for said substrate.

9. The device as claimed in claim 8, wherein said temperature-regulating circuit is produced in the form of a three-dimensional interconnection block that is fastened to the other portion of said package, said protective layer encapsulating said package and said block, and also the optical and electrical connections for said temperature-regulating element and for said electronic regulating circuit over said minimum length.

10. The device as claimed in claim 9, wherein the fastening of said component to the substrate, the fastening of the substrate to said protuberances and the fastening of the block to the second portion of the package are effected by adhesive bonding.

11. The device as claimed in claim 8, wherein said temperature-regulating circuit is produced in the form of a three-dimensional interconnection block and in that said block constitutes the second portion of said package and is fastened by adhesive bonding to said first portion of the package in order to define said internal volume containing the component, said protective layer encapsulating said first portion, said block and the optical and electrical connections for said temperature-regulating element and for said electronic regulating circuit over said minimum length.

12. The device as claimed in claim 1, wherein said component is an optical or optoelectronic component fastened to a first face of a plane substrate, in which the other face of said substrate carries, facing the component, a temperature-regulating element, which is supplied by an electronic temperature-regulating circuit, in which said temperature-regulating circuit is produced in the form of a three-dimensional interconnection block, in which said block constitutes the second portion of said package and is fastened by adhesive bonding to said first portion of the package in order to define said internal volume containing the component, said protective layer encapsulating said first portion, said block and the optical and electrical connections for said electronic regulating circuit over said minimum length, and in which said block includes, toward the inside of the package, conducting pins approximately perpendicular to the internal face of said block in order to mechanically fasten said substrate and the component and to serve for electrically connecting said temperature-regulating element to said electronic regulating circuit.

13. The device as claimed in claim 12, wherein said temperature-regulating element is a Peltier-effect cooling element, in which said first portion of the package is made of a material that is a good thermal conductor and in that, between the warm face of the cooling element and the internal face of said first portion of the package, a thermal connecting layer is interposed in order to dissipate heat.

14. The device as claimed in claim 1 wherein the connections and/or links leaving the package are stripped at the outlet of said package over a predetermined distance and in which said mineral protective layer extends only up to the stripped portions of the connections and/or links, in order to reduce said predetermined minimum length.

15. The device as claimed in claim 8, wherein the connections and/or links leaving the package are stripped at the outlet of said package over a predetermined distance and in which said mineral protective layer extends only up to the stripped portions of the connections and/or links, in order to reduce said predetermined minimum length.

16. The device as claimed in claim 12, wherein the connections and/or links leaving the package are stripped at the outlet of said package over a predetermined distance and in which said mineral protective layer extends only up to the stripped portions of the connections and/or links, in order to reduce said predetermined minimum length.
